(19) United States
(12) Patent Application Publication
(10) Pub. No.: US 2022/0329039 A1
(43) Pub. Date: Oct. 13, 2022

(54) MICROMECHANICAL OPTICAL COMPONENT AND MANUFACTURING METHOD

(71) Applicant: Robert Bosch GmbH, Stuttgart (DE)

(72) Inventor: Stefan Pinter, Reutlingen (DE)

(21) Appl. No.: 17/761,999

(22) PCT Filed: Jul. 28, 2020
(86) PCT No.: PCT/EP2020/071233

§ 371 Date: Mar. 18, 2022

(30) Foreign Application Priority Data
Oct. 1, 2019 (DE) 10 2019 215 098.5

(51) Int. Cl. H01S 5/02257; H01S 5/02253; H01S 5/02255; H01S 5/02326; H01S 5/024

(52) U.S. Cl. CPC H01S 5/02257; H01S 5/02253; H01S 5/02255; H01S 5/02326; H01S 5/02469

(57) ABSTRACT

A micromechanical optical component having a substrate, a spacer, and a cover, which are positioned one above the other and delimit a hermetically sealed cavity. A semiconductor laser is situated in the cavity, on the substrate. An optical element, which is attached to the spacer, is positioned in a beam path of the semiconductor laser. A method for manufacturing a micromechanical optical component is also described.

### FIELD

The present invention relates to a micromechanical optical component having a substrate, a spacer, and a cover, which are positioned one above the other and delimit a hermetically sealed cavity; a semiconductor laser being situated in the cavity, on the substrate.

### BACKGROUND INFORMATION

Laser diodes require a hermetically sealed housing for sealing them off from environmental influences, for further processing, for connecting them electrically, and for dissipation of heat. The packaging must also have an optical outlet window for the laser beam, which is hermetically sealed, as well. Presently, laser diodes are put into, e.g., a metal housing (TO “metal can;” TO=transistor outline). The electrical contact electrodes and the optical window for emergence of the beam are glazed into the housing hermetically. The laser diodes are soldered onto, e.g., an electrically insulating ceramic having high thermal conductivity. Electrical circuit traces and also electrical vias are deposited on the ceramic. The laser diodes are connected electrically to the circuit traces either by soldering or by wire bonding. The ceramic is then soldered into the metal housing. In this context, the conduction of heat to the housing and the electrical contacting with the contact electrodes are established.

Although all of the dimensions of the laser diode components themselves are substantially less than 1 mm, the housing (e.g., a TO38 housing having a laser diode) has a component volume, which is over 30 mm³. For wearable devices, such as AR (augmented reality) or VR (virtual reality) glasses, three laser diodes are required as light sources for the colors red, green and blue.

In addition to the laser diodes, still other optical elements are necessary for beam shaping. Miniaturization of the packaged laser diodes is an enormous advantage for wearable devices.

Designs for wafer-level packaging of edge-emitting laser diodes, by which low component housing volumes are attainable, are described in the U.S. Pat. No. 9,008,139 B2, and German Patent Application Nos. DE 10 2015 108 117 A1, DE 10 2015 208 704 A1, DE 10 2016 213 902 A1 and DE 10 2017 104 108 A1.

### SUMMARY

The present invention relates to a micromechanical optical component having a substrate, a spacer, and a cover, which are positioned one above the other and delimit a hermetically sealed cavity; a semiconductor laser being situated in the cavity, on the substrate. In accordance with an example embodiment of the present invention, a separate optical element, which is attached to the spacer, is positioned in a beam path of the semiconductor laser. This allows laser diodes having a selectable beam outlet direction, integratable photodiodes, and optical beam shaping elements to be housed in a hermetically sealed manner. The optical element may be positioned freely within broad limits in the installation location and installation angle, unlike in the related art, where a mirror is produced by processing and coating the spacer itself. In addition, the present invention allows an optical element to be used, whose material, surface quality, surface coating, and shape are freely selectable.

One advantageous refinement of the micromechanical optical component of the present invention provides for the optical element to be attached to an inner side or to an outer side of the spacer. In this manner, a suitable beam geometry may be advantageously provided for the semiconductor laser.

One advantageous refinement of the micromechanical optical component of the present invention provides for the substrate to be a single-layer or multilayer ceramic substrate. In this manner, a suitable installation height of the semiconductor laser is advantageously determined, and electrical contacting and adequate heat dissipation for the semiconductor laser are enabled.

One advantageous refinement of the micromechanical optical component of the present invention provides that on an inner side, the spacer include a beam trap in the form of a micromechanical pattern, in particular, slotted trenches, for light from the semiconductor laser. This advantageously suppresses scattered light in the interior of the cavity, which could be reflected, in particular, back into the laser and, thus, interfere with the laser.

One advantageous refinement of the micromechanical optical component of the present invention provides for the spacer to include, on an outer side, a micromechanical pattern for cooling, in particular, slotted trenches. In this manner, suitable heat dissipation is made possible for the semiconductor laser.

One advantageous refinement of the micromechanical optical component according to the present invention provides for the spacer to be made of silicon, in particular, monocrystalline silicon. The spacer may advantageously be fabricated in a suitable manner from a silicon wafer having an appropriate crystal orientation.

One advantageous refinement of the micromechanical optical component of the present invention provides that the optical element be a mirror for reflecting light from the semiconductor laser. Using a mirror, the beam path of the semiconductor laser may advantageously be directed perpendicularly to a major plane of the substrate or to the cover.

In this context, it is particularly advantageous for the cover to be made of a material transparent to light from the semiconductor laser, in particular, glass. This advantageously allows laser light to be transmitted through the cover.

In this context, it is also particularly advantageous for the cover to have an antireflection coating on an inner side or also on an outer side. In this manner, back reflection of laser light is advantageously prevented.

It is also particularly advantageous for some regions of the cover to have a radiation absorption coating on an inner side. This advantageously allows scattered light to be absorbed.

One advantageous refinement of the micromechanical optical component of the present invention provides that the optical element be an optical window for transmitting light from the semiconductor laser. Using a window, the beam path of the semiconductor laser may advantageously be directed parallelly to a major plane of the substrate or to the cover.

In this context, it is particularly advantageous for the optical window to have an antireflection layer on an inner side or also on an outer side. In this manner, back reflection of laser light is advantageously prevented.

In this context, it is also particularly advantageous for the cover to have, on an inner side, a beam trap in the form of a micromechanical pattern, in particular, slotted trenches, for light from the semiconductor laser. This advantageously suppresses scattered light in the interior of the cavity.

The present invention also relates to a method for manufacturing a micromechanical optical component. In accordance with an example embodiment of the present invention, the method includes:

A—providing a silicon wafer as a spacing wafer;
B—depositing and patterning a mask for KOH-etching on the spacing wafer;
C—producing a cavity in the spacing wafer, starting from a back side of the wafer, using KOH etching;
D—producing a through-opening to a front side of the spacing wafer, in a first flank of the cavity;
E—attaching an optical element to the first flank with the aid of a glass solder, the through-opening being covered and hermetically sealed;
F—positioning and attaching a cover wafer onto and to the back side of the spacing wafer, respectively;
G—producing an opening to the cavity on the front side of the spacing wafer;
H—attaching a substrate having a semiconductor laser positioned on it, to the front side of the spacing wafer, the semiconductor laser being introduced into the cavity, and the opening being covered and sealed hermetically by the substrate.

The micromechanical optical component may be advantageously manufactured on the wafer level, using this method. Using the separate substrate for the semiconductor laser and the separate optical element, a desired beam path may be provided and adjusted.

One advantageous refinement of the method of the present invention provides that in step D, the through-opening be produced by anisotropic etching of the spacing wafer, and that in step E, the optical element be supplied from the back side of the spacing wafer and be attached to the first flank on an inner side of the cavity. In this context, the first flank is advantageously formed by an etching front of the KOH-etching. The optical element is advantageously introduced into the cavity and secured in its interior, which means that a particularly compact and robust micromechanical optical component may be produced.

One advantageous refinement of the method of the present invention provides that in step D, the first flank and the through-opening be produced by sawing or also grinding the spacing wafer on its front side, and that in step E, the optical element be supplied from the front side of the spacing wafer and attached to the first flank, on an outer side of the cavity.

After step H, it is also advantageous that in a step I, the micromechanical optical component is sectioned by sawing or also grinding or also trench-etching through the spacing wafer and the cover wafer. In this manner, the largest part of the manufacturing method may advantageously be carried out on the wafer level, which means that adjustment, testing and handling of the micromechanical optical components are made easier.

The micromechanical optical component of the present invention is distinguished by a very small volume. In principle, a plurality of laser diodes, e.g., for the colors red, green, blue and infrared, may also be encapsulated in a housing. The emergence of the beam may alternatively take place perpendicularly or parallelly to the assembly plane of the component housing on the substrate (e.g., on a circuit board). Photodiodes may be integrated for the measurement and control of the radiant power of the laser diodes, and optical elements may be integrated for the beam-shaping. Low production costs are achievable, since the manufacturing method may be implemented in the circuit board, on the wafer level. The manufacturing method utilizes materials and operations, which are deployed for MEMS in mass production. The manufacturing method in silicon glass technology has a particularly high level of benefit at low production costs. The present invention allows the lost power of the semiconductor laser to be dissipated effectively. The capability of the component of being processed further as a SMT component is also advantageous. Not only windows or plane mirrors, but also beam-shaping elements, such as lenses and concave mirrors, may be integrated as optical elements. During the manufacturing of the component of the present invention, fine adjustment of the laser diode with respect to the optical element is advantageously possible. Scattered radiation escaping from the housing may be advantageously minimized by optical absorption layers or patterns. The separate optical element in the form of a mirror advantageously allows low optical losses or even low levels of scattered radiation, due to high optical reflectivity and surface quality. Low optical losses or also low levels of scattered radiation at the optical outlet window of the device may be advantageously achieved by high optical quality and a double-sided antireflection layer.

### BRIEF DESCRIPTION OF THE DRAWINGS

FIG. 1 shows a schematic cross section of a micromechanical optical component of the present invention in a first exemplary embodiment of the present invention.

FIG. 2 shows a schematic cross section of a micromechanical optical component of the present invention in a second exemplary embodiment of the present invention.

FIG. 3 shows a schematic cross section of a micromechanical optical component of the present invention in a third exemplary embodiment of the present invention.

FIG. 4 shows a schematic cross section of a micromechanical optical component of the present invention in a fourth exemplary embodiment of the present invention.

FIG. 5 shows a schematic cross section of a micromechanical optical component of the present invention in a fifth exemplary embodiment of the present invention.

FIG. 6 shows a schematic cross section of a micromechanical optical component of the present invention in a sixth exemplary embodiment of the present invention.

FIG. 7 shows a schematic cross section of a micromechanical optical component of the present invention in a seventh exemplary embodiment of the present invention.

FIG. 8 shows a schematic cross section of a micromechanical optical component of the present invention in an eighth exemplary embodiment of the present invention.

FIGS. 9A, 9B, and 9C show a first exemplary embodiment of the method of the present invention for manufacturing a micromechanical optical component, including mounting an optical element on the back side of a spacing wafer.

FIGS. 10A and 10B show a second exemplary embodiment of the method of the present invention for manufacturing a micromechanical optical component, including mounting an optical element on the front side of a spacing wafer.

FIG. 11 schematically shows a method in accordance with an example embodiment of the present invention for manufacturing a micromechanical optical component.

FIGS. 12A and 12B show a method of manufacturing an optical element for a micromechanical optical component in a first exemplary embodiment of the present invention, the production of a mirror.

FIGS. 13A and 13B show a method of manufacturing an optical element for a micromechanical optical component in a second exemplary embodiment of the present invention, the production of an optical window.

FIG. 14 shows a method of manufacturing an optical element for a micromechanical optical component in a third exemplary embodiment of the present invention, the production of an optical window having a lens.

FIG. 15 shows a method of manufacturing an optical element for a micromechanical optical component in a fourth exemplary embodiment of the present invention, the production of a curved mirror.

### DETAILED DESCRIPTION OF EXAMPLE EMBODIMENTS

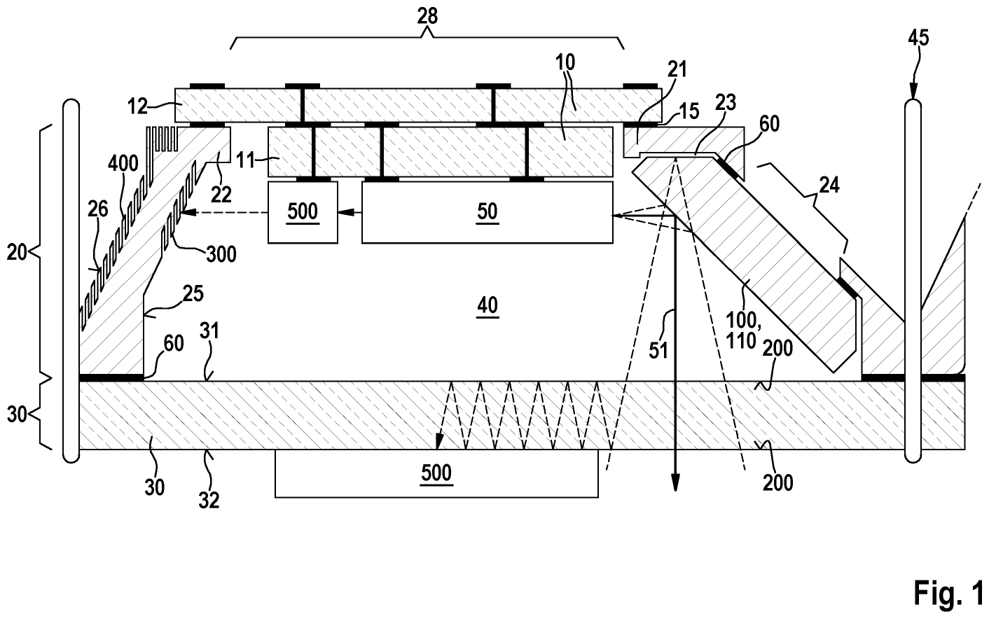

FIG. 1 shows a schematic cross section of a micromechanical optical component of the present invention in a first exemplary embodiment. Shown, is a device having a substrate 10, a spacer 20, and a cover 30, which are positioned one on top of the other and delimit a hermetically sealed cavity 40; a semiconductor laser 50 being situated in the cavity, on the substrate. According to the present invention, a separate optical element 100, that is, one different from the spacer, which is attached to the spacer, is positioned in a beam path 51 of the semiconductor laser. In this exemplary embodiment, the optical element is a mirror 110 for reflecting light from the semiconductor laser. The cover is made of a material transparent to light from the semiconductor laser, in this case, glass. The cover has an antireflection layer 200 on an inner side 31 and on an outer side 32. On an inner side 25, the spacer includes a beam trap 300 in the form of a micromechanical pattern, in this case, slotted trenches, for light from the semiconductor laser. On an outer side 26, the spacer includes a micromechanical pattern for cooling 400, in this case, slotted trenches. Substrate 10 is a multilayer ceramic substrate made up of a first ceramic 11 and a second ceramic 12.

The device is produced on the wafer level, and to that end, is made up of a cover wafer for the cover, a silicon spacer wafer for the spacer, an optical element, in this case, a mirror, and a single-layer or multilayer ceramic substrate including the soldered-on laser diode.

For the specific embodiment described here, in which the beam emerges perpendicularly, the cover wafer is made of optically transparent glass and has an antireflection layer on both sides to increase the transmission (that is, to reduce reflective beam losses). The spacer wafer or spacing wafer is made of silicon having a special crystal orientation. The crystal orientation is such, that a 45° incline of first flank 21 of the cavity, to which the beam deflecting element is attached, is produced by KOH-etching. Standard silicon wafers have a crystal orientation, which yields 54.7° for both flanks. In order to change desired etching flank 21 to 45°, a crystal “misorientation” of −9.7° is necessary. This causes second flank 22 to change by +9.7° to 64.4°. To solder the ceramic substrate onto the front side of the spacer, the spacer wafer is provided with and patterned to include suitable metallic layers capable of being soldered.

After the patterning of the metallic layer stack, a through-opening 24 is introduced on first flank 21, as well as a groove 23 for optical element 100, using trench-etching. During this trench-etching, “beam absorber structures” 300 may optionally be introduced on second flank 22. These structures are used to absorb unwanted radiation, which emerges at the edge of the laser diode that is situated oppositely to the actual emission edge.

Mirror 110 is then positioned onto first flank 21, into groove 23. The groove prevents the element from slipping away out of its desired position. In the wafer composite, the optical element (made of silicon or glass) has been previously provided with a highly reflective layer (e.g., aluminum or even silver) on one side, using a deposition method, and in this manner, a mirror was produced. In the wafer composite, as well, glass solder 60 is applied to the opposite side of the beam deflection element, e.g., by screen-printing, and hardened in a tempering step (“prebake”).

A sectioning operation (sawing) follows, in which individual chips are produced from the wafer. The edge profile of the sectioning is advantageously designed to form a chamfer or recess 45. The shape and dimension of this edge profile and of the groove ensure that after the placement, the element remains in its correct position and does not slip. The edge profile may be produced by selecting one or more saw blades having suitable profiles, or by a so-called step-cut (two consecutive saw cuts having a suitable width and depth). The sectioning is also possible by trench-etching. With the aid of a (pick and place) component insertion unit, the sectioned chips are introduced at an angle of 45° into the spacer wafer, onto first flanks 21, and into groove 23. After all of first flanks 21 are populated, a heating operation follows, in which the glass solder softens. In this heating operation, a differential pressure is generated between the front and back sides of the spacer wafer, through which the beam deflection elements are pressed against first flanks 21. Glass solder 60 wets the flank and is squeezed, and after cooling, an intimate and hermetically sealed connection of the mirror with the spacer results.

In a next step, the glass cover wafer supplied with a two-sided antireflection coating 200 is provided with glass-solder sealing structures via screen-printing, and prehardened (“prebake”). Subsequently, in a conventional wafer bonder, the cover wafer is joined to the spacer wafer intimately and hermetically at an increased temperature and mechanical contact pressure, and in a suitable atmosphere.

The cavity 40 situated between the cover wafer and spacer wafer is opened from the front side of the spacer wafer, by trench-etching the silicon. An opening 28 is formed. During this trench-etching, “cooling structures” 400 may also be introduced on the outer surface of second flank 22 or, in general, on surfaces exposed at the front side towards the outside. These structures are used for increasing the surface area of the component and bring about an improvement in the removal of heat from the component, that is, they improve cooling. The prefabricated ceramic substrate 10, on which laser diode 50 was previously soldered and contacted, is then placed. The placement is carried out with the aid of a (pick and place) component inserting device, or with the aid of a flip-chip bonder. In a heating operation, the populated composite of spacer wafer and cover wafer is soldered to the ceramic substrate at an elevated temperature, in a suitable atmosphere. In this context, an intimate and hermetic soldered connection 15 is formed between the ceramic substrate and the spacer wafer. Through this, opening 28 is closed again, and laser 50 is situated in cavity 40. Since the performance of the laser diodes may be harmed by overly high temperatures, a suitable metallic coating on the ceramic and on the spacer wafer, as well as a suitable solder, are required. However, this solder should not melt again during the subsequent SMD mounting operation that utilizes reflow-soldering (temperatures of approximately 260° C.)

The wafers are then sectioned into chips, the micromechanical optical component of the present invention. The chips are suitable for further processing for SMD mounting, e.g., on a (flexible) circuit board. To that end, the chips are turned over, placed with the side of the ceramic on the provided mounting substrate, and soldered on.

In many applications, a photodiode 500 is necessary for measuring the radiant power, for example, in a tricolor laser module for the color management. As an option, a photodiode may be placed in the cavity on the side of the semiconductor opposite to the emission point of the laser. This photodiode is attached to the ceramic, and also contacted on it. Alternatively, the photodiode may also be placed onto the outer side 32 of the cover wafer, e.g., next to the emerging beam, and attached with the aid of transparent adhesive. It detects the scattered radiation. The contacting is possible, using wire bonding. Other types of application and contacting, for example, on a separate flexible substrate, are likewise possible.

By suitably sizing cavity 40, the opening 28 to the front side, as well as ceramics 10, 11, 12, which occlude the cavity over the opening, a plurality of laser diode elements, e.g., of different colors, may also be packaged, in principle, in a housing.

In the case of using a flip-chip bonder, fine adjustment of the laser diodes with respect to the housing or with respect to the optical elements is possible. In this context, during the positioning of the carrier ceramic, the laser is caused to emit a beam, and the beam position is ascertained, e.g., with the aid of a CCD camera. Using corrections of the positioning, the beam is brought into correspondence with the nominal position (active alignment). Such active alignment may only correct tilting (ρ about the x axis and φ about the y axis) and elevation changes (in z) of the laser diodes on the ceramic with respect to the housing, to a highly limited extent, since this could result in leaky soldered connections. When the lateral (x, y) and rotational (θ) positioning are correct, the ceramic is soldered by rapid, local heating of the ceramic.

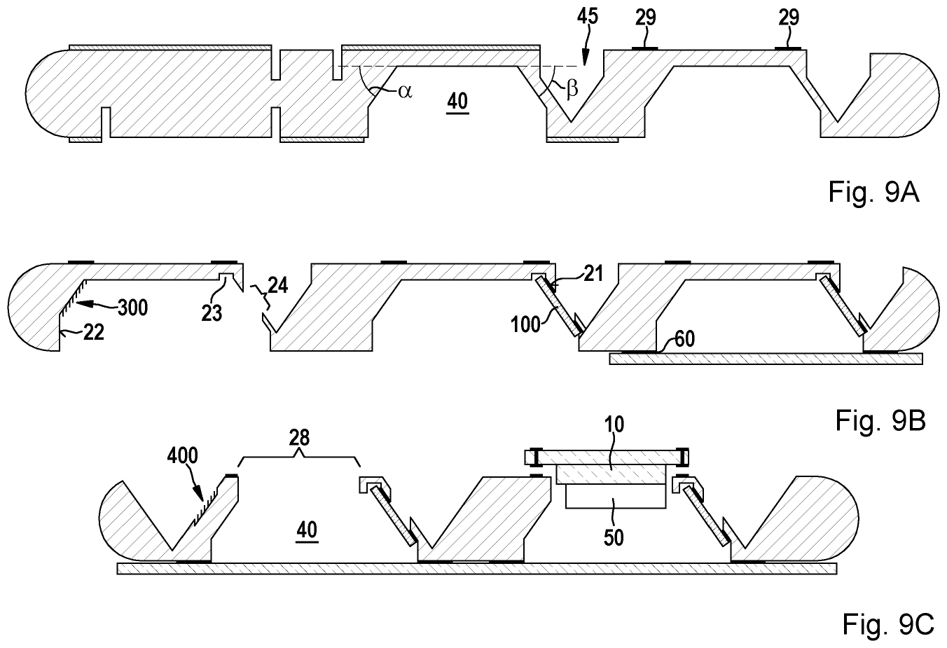

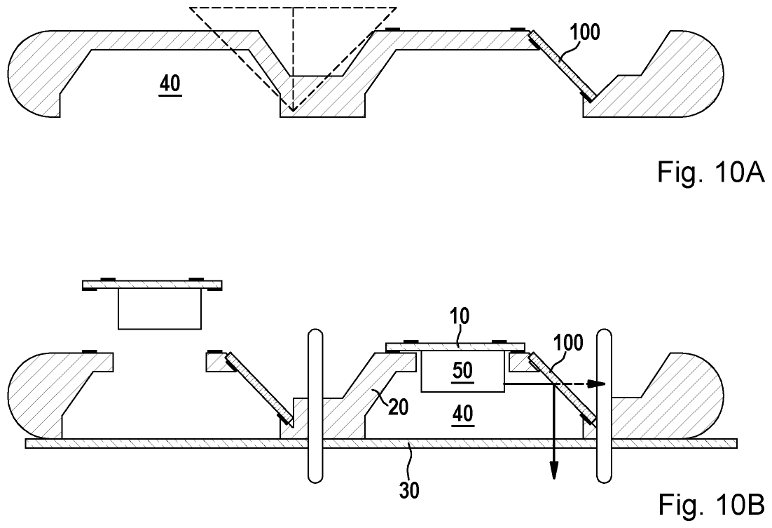

Two exemplary embodiments of the method of the present invention for manufacturing the micromechanical optical component are schematically represented further down in FIGS. 9A-9C and 10A and 10B.

To thermally dissipate the lost power of the laser diode, a material having very high thermal conductivity may be used instead of first ceramic 11. This material may be used as a heat conductor. In this case, the electrical contacting of at least one electrode of the laser diode and of the photodiode is carried out directly by wire bond with second ceramic 12.

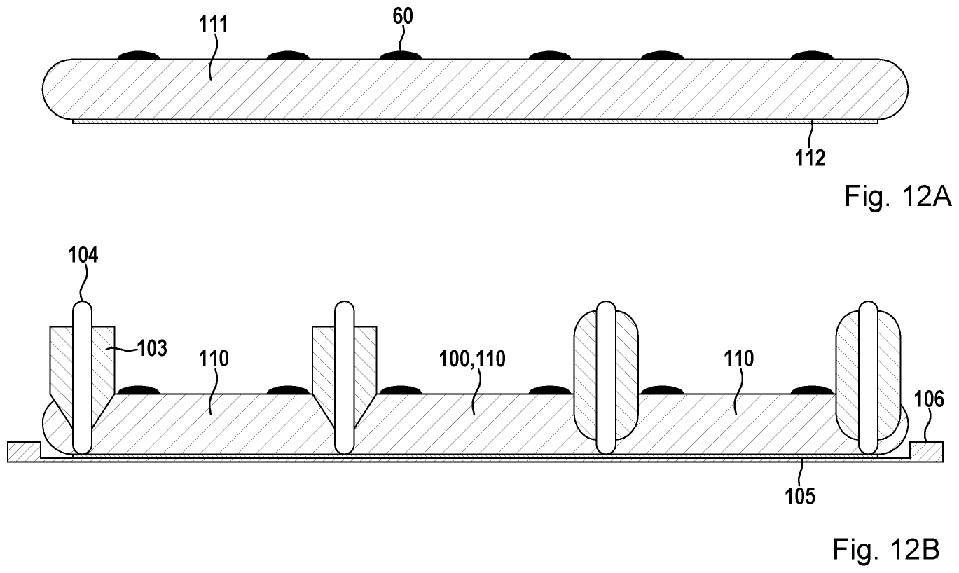

Since the beam deflection elements, beam deflection elements having a concave mirror, glass windows, glass windows having lenses, as well as their respective coatings with ARC (two-sided) or by reflective layers, are produced in the wafer composite, a very high optical quality is attainable on the two sides. The elements may be produced on glass or silicon wafers. Owing to this high optical quality, unwanted scattered radiation may be minimized, the optical transmission may be maximized, and the beam shape may be optimized. Aluminum or also silver may be used as a reflective layer. Silver reflective layers have the highest reflectivity and render minimal beam intensity losses possible. Passivation of the reflective layers to prevent their degradation by environmental influences must only be used for protection up to their hermetic encapsulation in the component cavity. Therefore, passivation on the sectioning edges of the elements is not necessary. Corresponding methods for their manufacture are schematically shown further down in FIGS. 12A, 12B, 13A, 13B, 14, 15.

The edge profile produced during the sectioning may be varied freely as a function of the profile of the grinding disks. It is also possible to section the silicon deflection elements by trench-etching. The special edge profile for these elements is only necessary on the edges, which are seen in cross section on the figures.

All of the exemplary embodiments may be combined with each other, if practical.

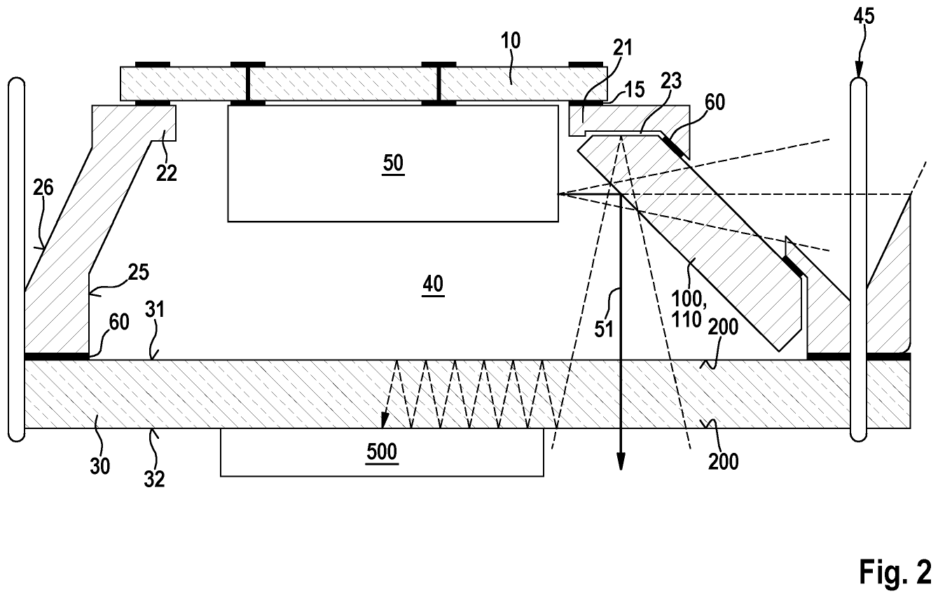

FIG. 2 shows a schematic cross section of a micromechanical optical component of the present invention in a second exemplary embodiment. In this specific embodiment, in contrast to the first exemplary embodiment, the two-layer ceramic is replaced by a single-layer ceramic substrate 10, and the thickness of laser chip 50 is increased appropriately. The component in the example has no photodiode, no beam absorber structures, and no cooling structures.

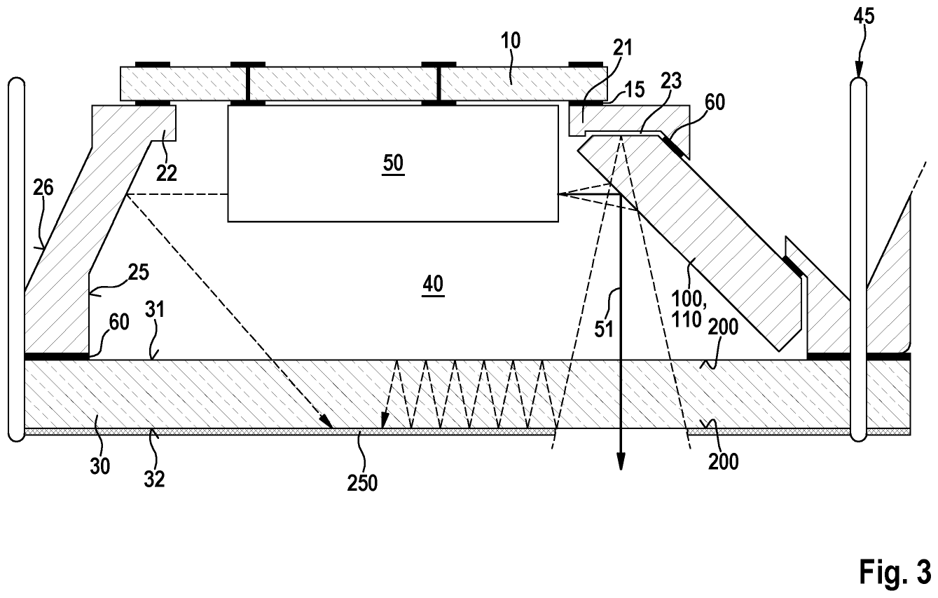

FIG. 3 shows a schematic cross section of a micromechanical optical component of the present invention in a third exemplary embodiment. In this specific embodiment, a radiation absorption layer 250, for example, applied by screen-printing, is on the outer surface of the cover wafer. However, the layer may also be produced by deposition and lithographic patterning of, for example, black chrome on the front or back side of the cover wafer. This radiation absorption layer 250 on cover 30 prevents the unwanted escape of scattered light (=mask) from the micromechanical optical component. Unwanted scattered light is generated, for example, at the boundary surfaces of the cover wafer, or by light, which emerges on the side of the laser diode opposite to the emission point and is reflected by second flank 22.

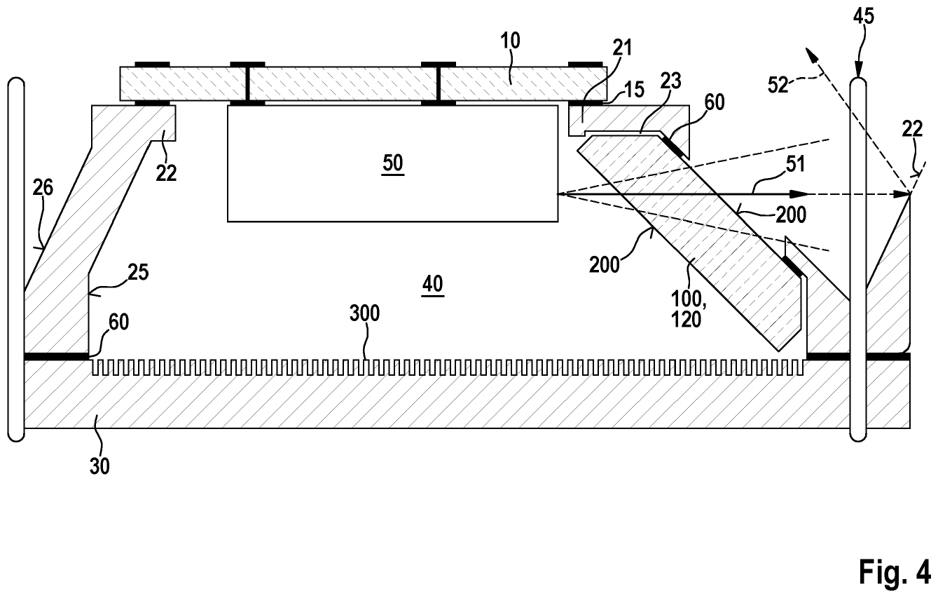

FIG. 4 shows a schematic cross section of a micromechanical optical component of the present invention in a fourth exemplary embodiment. In this specific embodiment, beam path 51 and the emergence of the beam from the micromechanical optical component, are horizontal. To that end, a glass window 120 provided with antireflection layer 200 on two sides is employed. The application of glass solder 60 and the sectioning and joining of this element are carried out in a manner analogous to the description of the first exemplary embodiment under FIG. 1.

The cover wafer is advantageously made of silicon. In order to minimize unwanted scattered radiation, e.g., due to reflections at the glass boundary surfaces, beam stopper structures 300 may be introduced on the side of the cover wafer directed towards cavity 40, using trench-etching.

In the wafer composite, the beam emerging horizontally through the glass window is reflected by the outer side of second flank 22. The position of these reflected beams 52 may be detected, e.g., on a CCD array. The positioning accuracy of emitting laser diode 50 with respect to the housing may be checked via a comparison with the desired position of the beam.

In this specific embodiment, the special crystal orientation may be dispensed with for the silicon spacer wafer material. The angles of flanks 21 and 22 may have the same inclination (54.7°).

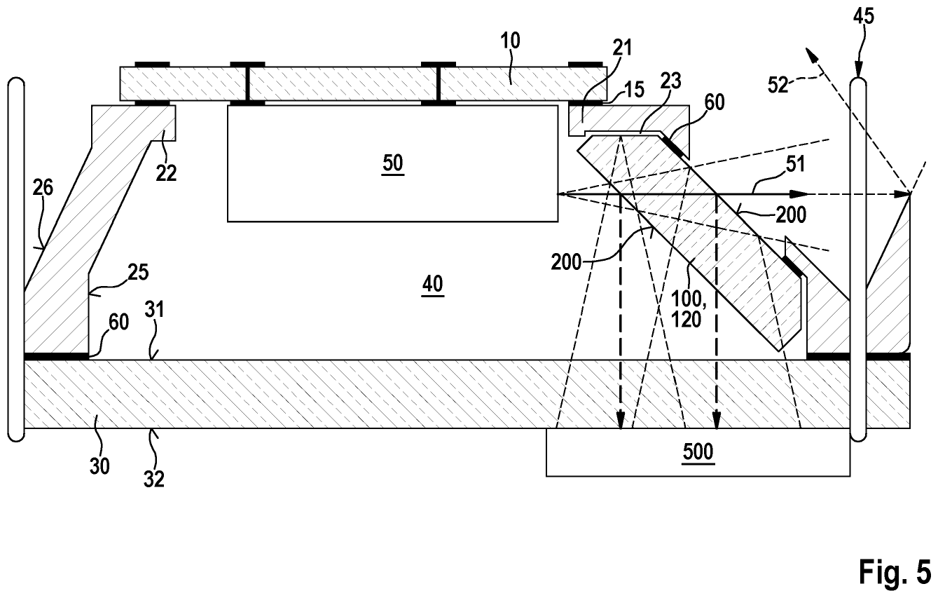

FIG. 5 shows a schematic cross section of a micromechanical optical component of the present invention in a fifth exemplary embodiment, including horizontal emergence of the beam and an integrated photodiode 500. In this instance, the cover wafer is made of optically transparent glass. In this case, a photodiode for measuring the radiant power may be mounted at a suitable location, preferably, in the optical path of the reflections generated at the boundary surfaces of outlet window 120.

In this specific embodiment, the special crystal orientation may be dispensed with for the silicon spacer wafer material. The angles of flanks 21 and 22 may have the same inclination (54.7°).

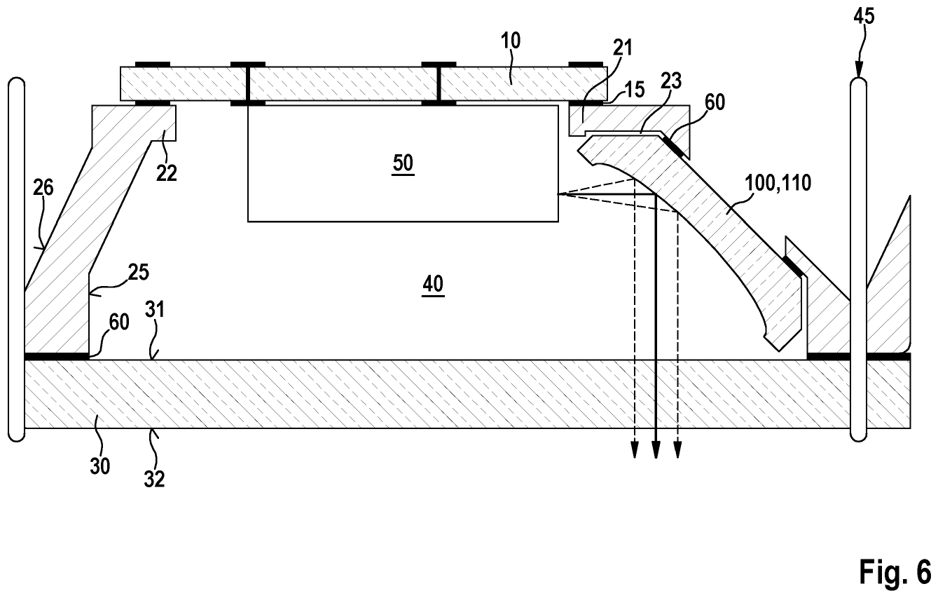

FIG. 6 shows a schematic cross section of a micromechanical optical component of the present invention in a sixth exemplary embodiment, including integrated beam shaping optics with perpendicular emergence of the beam. Optical element 100 is reflective and includes a depression having a specific depth profile on the side directed towards the cavity. Thus, it is a concave mirror 110. The shape of the depression is to be selected in such a suitable manner, that the divergent beam striking it is focused/collimated (beam shaping). However, other profiles are also possible as a function of the application. Wafers including such elements are available on the market or may be produced, using conventional MEMS processes.

A suitable reflective layer may be deposited on the surface of concave mirror 110. The mirror may be made of silicon or glass and may also be coated on the wafer level or in the wafer composite. The application of glass solder 60 and the sectioning and joining of this element is carried out in a manner analogous to the description in exemplary embodiment 1.

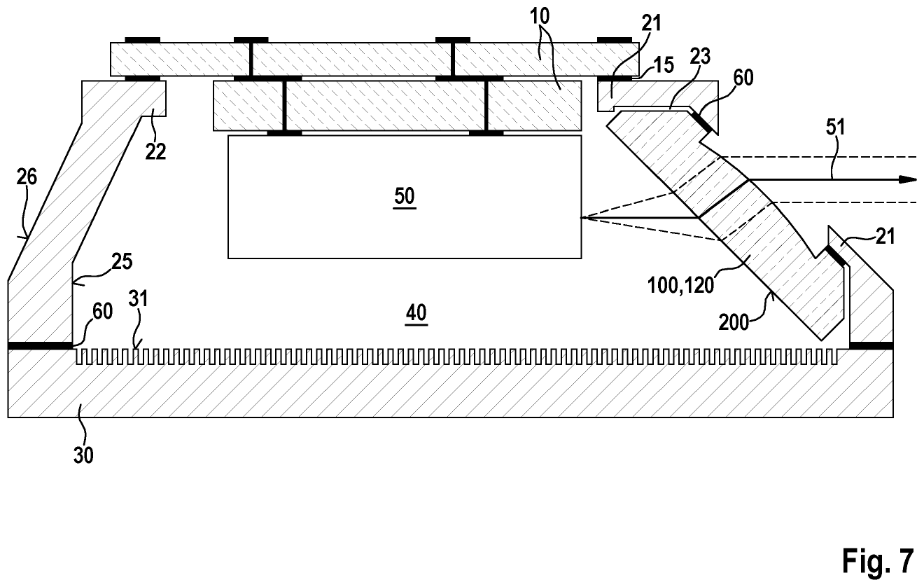

FIG. 7 shows a schematic cross section of a micromechanical optical component of the present invention in a seventh exemplary embodiment, including integrated beam shaping optics with horizontal emergence of the beam. Optical element 100 is made of glass and forms, for example, an aspheric plano-convex lens element in beam path 51. The convex side of the lens element is on the side of window 120 directed away from the cavity. The window, more precisely, the lens, is made of glass and is produced on the wafer level and/or in the wafer composite, and is also provided with an antireflection layer 200. Wafers having such elements are available on the market. The application of glass solder 60 and the sectioning and joining of this element are carried out in a manner analogous to the description in the first exemplary embodiment. However, other lens shapes for shaping the beam in a desired manner are also possible as a function of the application. In this specific embodiment, the special crystal orientation may be dispensed with for the silicon spacer wafer material. The angles of first and second flanks 21 and 22 may have the same inclination (54.7°). On an inner side 31, cover 30 includes, as a beam trap 300, a micromechanical pattern in the form of slotted trenches.

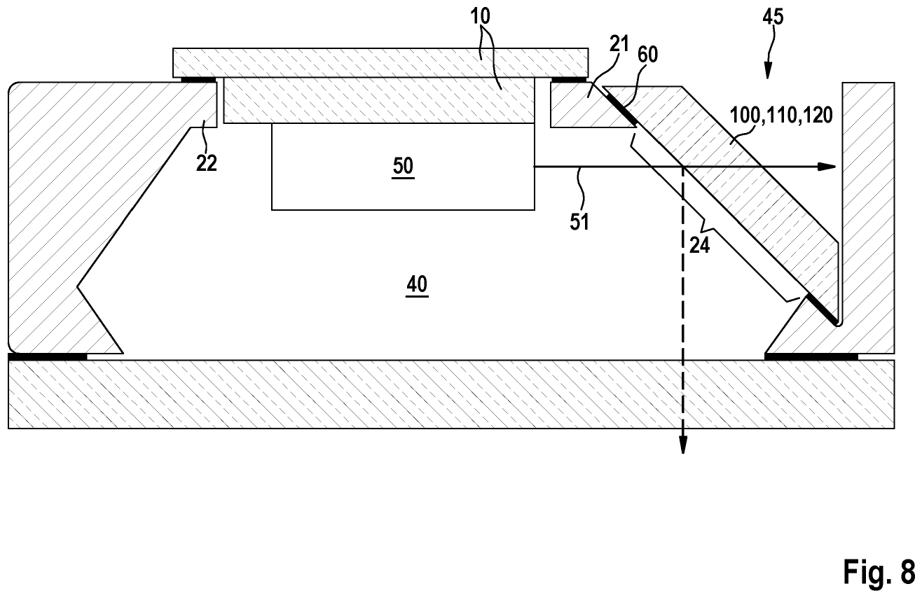

FIG. 8 shows a schematic cross section of a micromechanical optical component of the present invention in an eighth exemplary embodiment. In this variant, the beam may emerge both horizontally and perpendicularly. This is a function of the optical element 100 selected (window or mirror). In this specific embodiment, the special crystal orientation may be dispensed with for the silicon spacer wafer material. The angles of flanks 21 and 22 may have the same inclination (54.7°). After the KOH-etching of cavity 40 and the front-side structures, the 45° flank, onto which the glass window (or also deflection element) is positioned, is produced by introducing a recess 45 externally from the front side, using grinding. In this context, by cutting the back-side cavity, using the 45° grinding plane, an opening 24 is formed on first flank 21, as well as a sealing surface, which encircles the opening and is for the glass solder 60 of the window 120 or mirror 110 put on from the outside. The grinding profile is selected in such a manner, that selected optical element 100 falls by itself into the desired end position and also remains there (see also FIGS. 10A and 10B). The glass solder on the optical element is softened by a heating operation and squeezed due to a pressure difference between the front and back sides of the spacer wafer. In this context, after the cooling, the wetting produces an intimate and hermetic connection with the spacer wafer. Further down, FIGS. 10A and 10B schematically shows a variant of the manufacturing method for this specific embodiment, including the individual steps. It is possible to produce the cavities to have a different geometry, and, alternatively, using different patterning methods, such as trench-etching, as well.

FIGS. 9A, 9B, and 9C schematically show a first exemplary embodiment of the method of the present invention for manufacturing a micromechanical optical component, including mounting an optical element on the back side of a spacing wafer.

On the left, FIG. 9A shows the introduction of trenches, using anisotropic etching (trenching) from the front and back sides of the spacing wafer. The deposition and patterning of a KOH masking layer on the front side and the back side, as well as KOH-etching, is shown in the middle. Using the KOH-etching, cavity 40 is produced from the back side, and a recess 45 is introduced from the front side. The deposition of a metallic coating 29 onto the front side is shown on the right.

On the left, FIG. 9B shows the opening of a through-opening 24 in the spacing wafer between the front side and back side, more precisely, between recess 45 and cavity 40, using trenching; likewise, the production of a groove 23 and of beam absorption structures 300 on a second flank 22 from the back side of the wafer. The positioning of an optical element 100 onto first flank 21, into groove 23, as well as a heating operation for hermetically joining the optical element and spacing wafer, are shown in the middle. The hermetic joining of the cover wafer and spacing wafer with the aid of glass solder 60 is shown on the right.

On the left, FIG. 9C shows the opening of cavity 40 by producing an opening 28, and optionally, the production of cooling structures 400 by trenching from the front side of the wafer. The placement of laser diode 50 on ceramic substrate 10 and the joining of the substrate and spacing wafer with the aid of a heating operation, such as reflow soldering, thermocompression bonding, thermosonic bonding, laser soldering, flip-chip bonding, is shown on the right.

FIGS. 10A and 10B show a second exemplary embodiment of the method of the present invention for manufacturing a micromechanical optical component, including mounting an optical element on the front side of a spacing wafer.

This exemplary embodiment enables, in particular, the production of the micromechanical optical component in accordance with the eighth exemplary embodiment.

On the left, FIG. 10A shows the spacing wafer after the trenching on the back side and the KOH-etching of the front and back sides (analogous to the left and center of FIG. 9A). Through this, cavity 40 is introduced from the back side. By subsequent grinding or sawing, a first flank 21, in this case, a 45° flank, is introduced in recess 45, on the front side of the spacing wafer. The first flank is used as a mounting surface for the optical element. To that end, the saw may have different profiles, as represented schematically in the drawing by the dashed lines. Metallic coating 29 of the front side, the positioning of optical element 100 from the outside, that is, from the front side of the spacing wafer, and the subsequent heating process, the joining of the optical element to the spacing wafer, are shown on the right.

On the left, FIG. 10B shows the joining of the cover wafer to the spacing wafer. The placement and joining of the ceramic substrate to the spacing wafer and the sectioning of the chips, that is, of the micromechanical optical component, are shown on the right. The saw blades shown schematically stand for this.

It is possible to produce cavities 40 having a different geometry, and alternatively, using different patterning methods, such as trench-etching, as well.

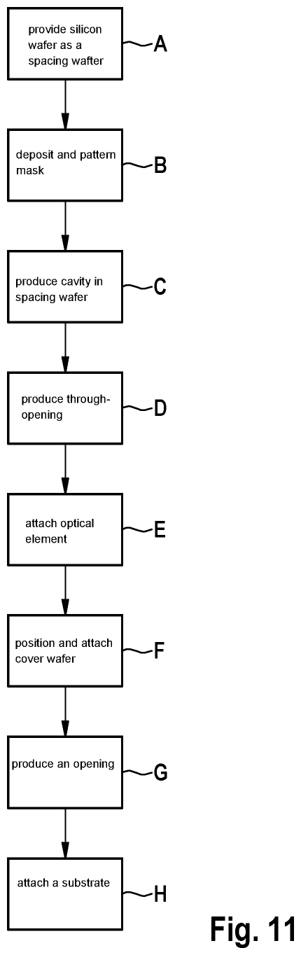

FIG. 11 schematically shows the method of the present invention for manufacturing a micromechanical optical component, including the principal steps:

A—providing a silicon wafer as a spacing wafer;
B—depositing and patterning a mask for KOH etching on the spacing wafer;
C—producing a cavity 40 in the spacing wafer, starting out from a back side of the wafer, using KOH-etching;
D—producing a through-opening 24 to a front side of the spacing wafer, in a first flank 21 of cavity 40;
E—attaching an optical element 100 to first flank 21 with the aid of a glass solder 60, through-opening 24 being covered and hermetically sealed;
F—positioning and attaching a cover wafer onto and to the back side of the spacing wafer, respectively;
G—producing an opening 28 to cavity 40 on the front side of the spacing wafer;
H—attaching a substrate 10 having a semiconductor laser 50 positioned on it, to the front side of the spacing wafer, the semiconductor laser being introduced into the cavity, and the opening 28 being covered and sealed hermetically by the substrate.

Subsequently, in a step I, the micromechanical optical component is sectioned by sawing or even grinding or even trench-etching through the spacing wafer and the cover wafer.

FIGS. 12A and 12B show a method of manufacturing an optical element for a micromechanical optical component in a first exemplary embodiment, the production of a mirror.

FIG. 12A shows a supplied mirror wafer 111, which is made of silicon or glass, is provided with a reflective layer 112 on a back side, and is provided with glass solder 60 in some regions on a front side. As an option, one or more protective layers or even passivation layers may also be situated on the reflective layer.

FIG. 12B schematically shows the sectioning of optical elements 100, in this case, mirrors 110, using two-stage sawing of mirror wafer 111, including two different lateral saw profiles 103, 104. In this context, different saw profiles are possible and represented here only symbolically. In addition, the mirror wafer is secured to a support frame 106 on a sawing tape 105.

Figured 13A and 13B show a method of manufacturing an optical element for a micromechanical optical component in a second exemplary embodiment, the production of an optical window.

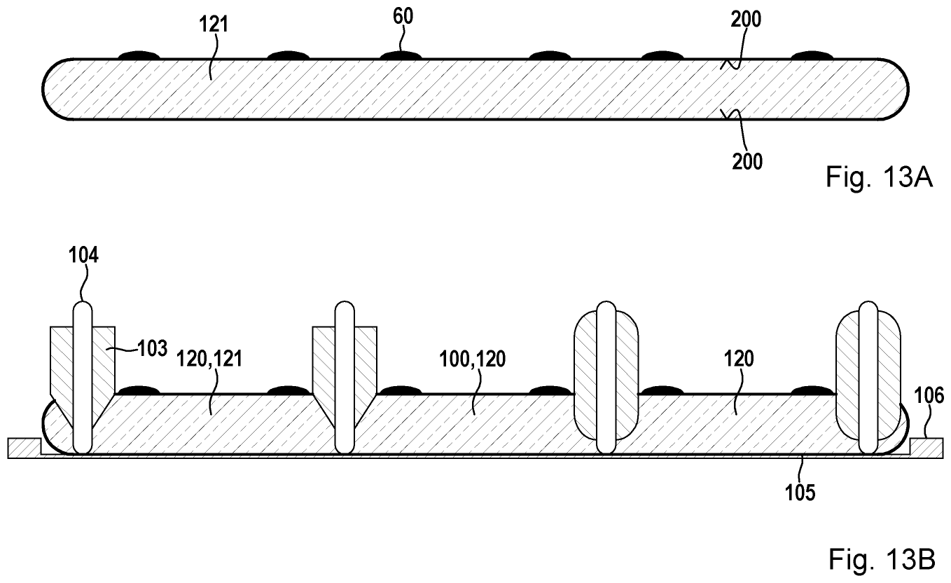

FIG. 13A shows a supplied window wafer 121, which is made of glass and is optionally provided with an antireflection layer 200 on one side or two sides. Alternatively, the wafer may also be made of a material other than conventional glass, as long as it transmits the wavelength of the semiconductor laser and may be attached to the silicon spacing wafer. On a front side, some regions of the window wafer are provided with glass solder 60.

FIG. 13B schematically shows the sectioning of optical elements 100, in this case, windows 120, using two-stage sawing of window wafer 121, including two different lateral saw profiles 103, 104.

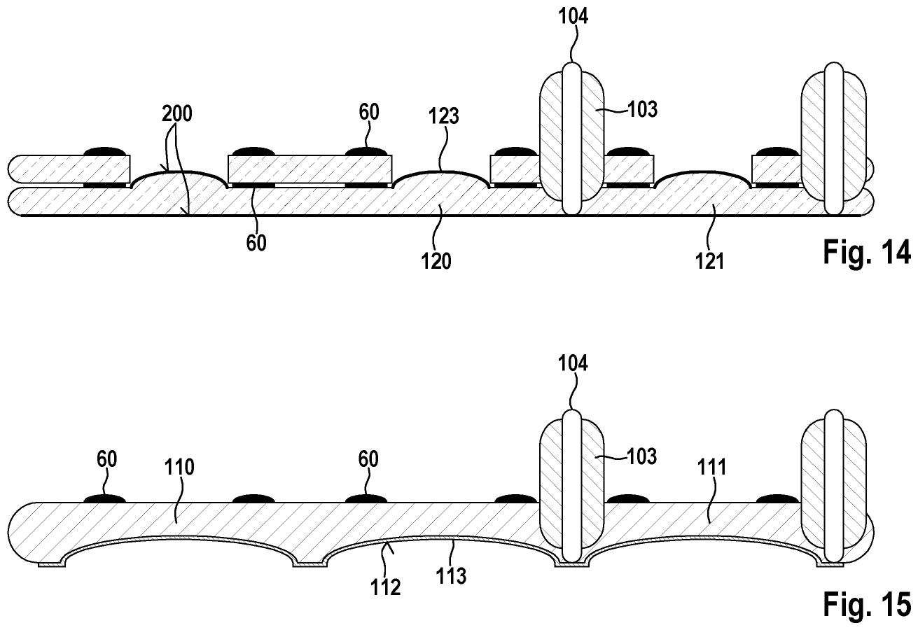

FIG. 14 shows a method of manufacturing an optical element for a micromechanical optical component in a third exemplary embodiment, the production of an optical window having a lens. A window wafer 121 is shown, which includes lens elements 123 for shaping the beam. Window wafer 21 may have an antireflection layer 200 on one side or two sides. A further glass or silicon wafer 122 is attached to window wafer 121 with the aid of glass solder 60. Further glass or silicon wafer 122 includes recesses and is positioned in such a manner, that these recesses surround the lens elements. In this instance, the glass solder surrounds the lens elements, as well, both on the free upper surface of further wafer 122 and between further wafer 122 and window wafer 121.

The sectioning of optical elements 100, in this case, the window 120 having lenses 123, by two-stage sawing through further wafer 122 and window wafer 121, including two different lateral saw profiles 103, 104, is shown on the right side of the figure.

FIG. 15 shows a method of manufacturing an optical element for a micromechanical optical component in a fourth exemplary embodiment, the production of a curved mirror. A mirror wafer 111 including concave mirror elements 113 for shaping the beam, as well as a reflective layer 112, is shown. The highly reflective layer is deposited on a back side of the mirror wafer and optionally includes another one or more passivation layers. On a front side, some regions of the mirror wafer are provided with glass solder 60.

The sectioning of optical elements 100, in this case, of mirror 110, using two-stage sawing of mirror wafer 111, including two different lateral saw profiles 103, 104, is shown schematically on the right side of the figure.

### LIST OF REFERENCE NUMERALS

10 substrate
11 first ceramic
12 second ceramic
13 electrical vias
15 soldered connection
20 spacer
21 first flank
22 second flank
23 groove
24 through-opening
25 inner side of spacer
26 outer side of spacer
28 opening
29 metallic coating
30 cover
31 inner side of cover
32 outer side of cover
40 cavity
45 recess
50 semiconductor laser
51 beam path
52 beams reflected in the wafer composite
60 glass solder
100 optical element
103 first lateral saw profile
104 second lateral saw profile
105 saw tape
106 support frame
110 mirror
111 mirror wafer
112 reflective layer
113 concave mirror elements
120 optical window
121 window wafer
122 further glass or silicon wafer
123 lens element
200 antireflection layer
250 beam absorption layer
300 beam trap
400 micromechanical pattern for cooling
500 photodiode

1-17. (canceled)

18. A micromechanical optical component, comprising:
a substrate, a spacer, and a cover, which are positioned one above the other and delimit a hermetically sealed cavity;
a semiconductor laser situated in the cavity, on the substrate;
wherein an optical element, which is attached to the spacer, is positioned in a beam path of the semiconductor laser.

19. The micromechanical optical component as recited in claim 18, wherein the optical element is attached to an inner side or to an outer side of the spacer.

20. The micromechanical optical component as recited in claim 18, wherein the substrate is a single-layer or multilayer ceramic substrate.

21. The micromechanical optical component as recited in claim 18, wherein on an inner side, the spacer includes a beam trap in the form of a micromechanical pattern, the pattern including slotted trenches for light from the semiconductor laser.

22. The micromechanical optical component as recited in claim 18, wherein on an outer side, the spacer includes a micromechanical pattern for cooling, the pattern including slotted trenches.

23. The micromechanical optical component as recited in claim 18, wherein the spacer is made of monocrystalline silicon.

24. The micromechanical optical component as recited in claim 18, wherein the optical element is a mirror for reflecting light from the semiconductor laser.

25. The micromechanical optical component as recited in claim 24, wherein the cover is made of a material transparent to light from the semiconductor laser, the material being glass.

26. The micromechanical optical component as recited in claim 25, wherein the cover has an antireflection layer on an inner side and/or on an outer side.

27. The micromechanical optical component as recited in claim 25, wherein some regions of an outer side of the cover include a radiation absorption layer.

28. The micromechanical optical component as recited in claim 18, wherein the optical element is an optical window for transmitting light from the semiconductor laser.

29. The micromechanical optical component as recited in claim 28, wherein the optical window has an antireflection layer on an inner side and/or on an outer side.

30. The micromechanical optical component as recited in claim 28, wherein on an inner side, the cover includes a beam trap in the form of a micromechanical pattern for light from the semiconductor laser, the pattern being slotted trenches,

31. A method for manufacturing a micromechanical optical component, comprising the following steps:
A) providing a silicon wafer as a spacing wafer;
B) depositing and patterning a mask for KOH-etching on the spacing wafer;
C) producing a cavity in the spacing wafer, starting out from a back side of the spacing wafer, using KOH-etching;
D) producing a through-opening to a front side of the spacing wafer, in a first flank of the cavity;
E) attaching an optical element to the first flank using a glass solder, the through-opening being covered and hermetically sealed;
F) positioning and attaching a cover wafer onto and to the back side of the spacing wafer;
G) producing an opening to the cavity on the front side of the spacing wafer;
H) attaching a substrate having a semiconductor laser positioned on it, to the front side of the spacing wafer, the semiconductor laser being introduced into the cavity, and the opening being covered and sealed hermetically by the substrate.

32. The method for manufacturing a micromechanical optical component as recited in claim 31, wherein:
in step D, the through-opening is produced by anisotropic etching of the spacing wafer; and
in step E, the optical element is supplied from the front side of the spacing wafer and is attached to the first flank, on an inner side of the cavity.

33. The method for manufacturing a micromechanical optical component as recited in claim 31, wherein:
in step D, the first flank and the through-opening are produced by sawing and/or grinding the spacing wafer on its front side; and
in step E, the optical element is supplied from the back side of the spacing wafer and is attached to the first flank, on an outer side of the cavity.

34. The method for manufacturing a micromechanical optical component as recited in claim 31, wherein after step H, in a step I, the micromechanical optical component is sectioned by sawing and/or grinding and/or trench-etching through the spacing wafer and the cover wafer.
